(19) United States
(12) Patent Application Publication
(10) Pub. No.: US 2025/0006531 A1
(43) Pub. Date: Jan. 2, 2025

(54) GAS CURTAIN DEVICE FOR FRONT OPENING UNIFIED POD

(71) Applicants: YU-HUA CHEN, FLORHAM PARK, NJ (US); AVEX-SG TECHNOLOGY INC., TAICHUNG CITY (TW)

(72) Inventors: JIN-BOR CHEN, TAICHUNG CITY (TW); TSAN-HUA HUANG, TAICHUNG CITY (TW); SHUN-YI HSU, TAICHUNG CITY (TW); TZU-HUNG HSU, TAICHUNG CITY (TW)

(21) Appl. No.: 18/546,803

(22) PCT Filed: Aug. 18, 2022
(86) PCT No.: PCT/US2022/075133

§ 371 Date: Aug. 17, 2023

(51) Int. Cl. H01L 21/673

(52) U.S. Cl. CPC H01L 21/67393; H01L 21/67386

(57) ABSTRACT

A gas curtain device for a front opening unified pod has a casing. The casing has an interior space. The interior space defines a transverse gas space, a curved gas space and a vertical gas space. At least one first gas guide plate is disposed in the transverse gas space and/or the curved gas space. The first gas guide plate has a plurality of first gas guide holes. A second gas guide plate is disposed at one end of the vertical gas space. The second gas guide plate has a plurality of second gas guide holes.

### FIELD OF THE INVENTION

The present invention relates to a front opening unified pod, and more particularly to a gas curtain device for a front opening unified pod.

### BACKGROUND OF THE INVENTION

In the semiconductor manufacturing industry, a front opening unified pod (FOUP) is a container used to protect, transport, and store wafers between processing steps. One of the most important functions is to prevent the internal wafers from being contaminated and affected by fine particles and moisture in the external environment during the transfer between different production machines. When a FOUP is transferred to the Load Port that attached on the EFEM for processing, the door on the front side of the front opening unified pod is opened, a clean and dry gas flow will be ejected downward through a gas curtain device disposed on the upper side of the load port door inside the equipment front end module (EFEM), thereby forming an invisible gas wall adjacent to the opening of the front opening unified pod, so as to prevent external fine particles and moisture from entering the front opening unified pod during wafer transfer process.

Wafers have very high requirements for fine particles-free and low moisture level in the environment. If the gas curtain device does not eject laminar flow with straight flow lines downward, but turbulent flow in a chaotic direction, it is very likely that the fine particles and the gas containing high moisture outside the front opening unified pod will be drawn into the front opening unified pod to cause contamination. As a result, the purpose of blocking fine particles and moisture from entering the front opening unified pod fails.

The top of a conventional gas curtain device has gas inlets that communicates with the inside of the gas curtain device. The inside of the gas curtain device has a transverse and slender space. The gas is introduced into the space of the gas curtain device via the gas inlets to form a gas flow. The space is provided with a plurality of gas vents which are spaced apart and arranged vertically. The gas flow is ejected out vertically and downwardly via the gas vents to form a gas curtain. However, the gas flow is quickly ejected via the gas vents then entering the space, there is no structural configuration for guiding the ejected gas flow to become laminar flow with straight flow lines. As a result, the gas flow is radially ejected from the gas vents, causing the gas flow to interfere with each other and the flow direction became chaotic.

After the gas flow is ejected from the gas vents to form the turbulent flow in a chaotic flow direction, which leads to the shortcoming that the fine particles and the gas containing high moisture in the EFEM will be drawn into the front opening unified pod.

### SUMMARY OF THE INVENTION

The primary object of the present invention is to provide a gas curtain device for a front opening unified pod for a clean and dry gas to be blown out close to a laminar flow manner, so as to minimize the formation of turbulent flow and prevent the moisture and fine particles in the equipment front end module from entering the front opening unified pod during wafer transfer process.

In order to achieve the foregoing object, the present invention provides a gas curtain device for a front opening unified pod. The gas curtain device comprises a casing, at least one first gas guide plate, and a second gas guide plate.

The casing has an interior space. The interior space defines a transverse gas space, a curved gas space communicating with the transverse gas space and a vertical gas space communicating with the curved gas space according to a cross section of the casing. The casing has at least one gas inlet communicating with the transverse gas space and a gas outlet communicating with the vertical gas space.

The at least one first gas guide plate is disposed in the transverse gas space and/or the curved gas space. The first gas guide plate has a plurality of first gas guide holes.

The second gas guide plate is disposed at one end of the vertical gas space adjacent to the gas outlet. The second gas guide plate has a plurality of second gas guide holes.

The number of the second gas guide holes is greater than the number of the first gas guide holes. A total area of the second gas guide holes of the second gas guide plate is greater than a total area of the first gas guide holes of the first gas guide plate.

Preferably, an area of a cross section at a distal end of the vertical gas space is greater than an area of a cross section of the transverse gas space and an area of a cross section of the curved gas space.

Preferably, the area of the cross section of the curved gas space is greater than the area of the cross section of the transverse gas space, and the area of the cross section at the distal end of the vertical gas space is greater than the area of the cross section of the curved gas space.

Preferably, the at least one first gas guide plate includes three first gas guide plates. One of the first gas guide plates is disposed in the transverse gas space, and the other two first gas guide plates are disposed in the curved gas space.

Preferably, the curved gas space is a downward curved gas space. One of the other two first gas guide plates is disposed at one end of the curved gas space in a horizontal direction, and the other is disposed at another end of the curved gas space in a vertical direction.

Preferably, the first gas guide plates and the second gas guide plate are replaceable structures for changing the number and the total area of the first gas guide holes and the second gas guide holes, thereby regulating the velocity and the uniformity of a gas flow passing through the first gas guide plates and the second gas guide plate.

Preferably, the first gas guide holes are distributed evenly or unevenly on the first gas guide plate for regulating the gas flow.

Preferably, the casing includes a left panel, a right panel, and a plurality of partitions.

In another embodiment, the casing includes a left casing and a right casing joined to the left casing.

In another embodiment, the casing is integrally formed.

### BRIEF DESCRIPTION OF THE DRAWINGS

FIG. 1 is a perspective schematic view according to a first embodiment of the present invention mounted on a load port of a front opening unified pod;

FIG. 2 is an exploded view according to the first embodiment of the present invention;

FIG. 3 is a side view according to the first embodiment of the present invention, showing the interior space of the casing without the gas guide plates;

FIG. 4 is a cross-sectional view according to the first embodiment of the present invention;

FIG. 5 is a planar schematic view of the first gas guide plate and the second gas guide plate according to the first embodiment of the present invention;

FIG. 6 is a schematic view according to the first embodiment of the present invention when in use;

FIG. 7 is a side view according to a second embodiment of the present invention, showing the interior space of the casing; and

FIG. 8 is a side view according to a third embodiment of the present invention, showing the interior space of the casing.

### DETAILED DESCRIPTION OF THE PREFERRED EMBODIMENTS

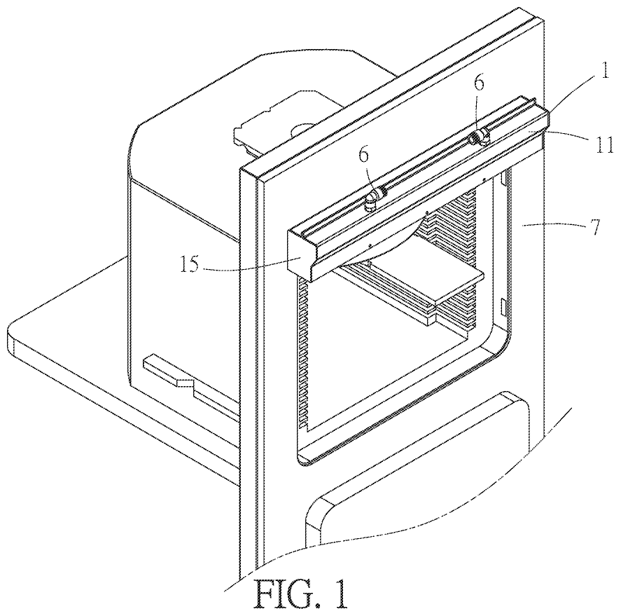

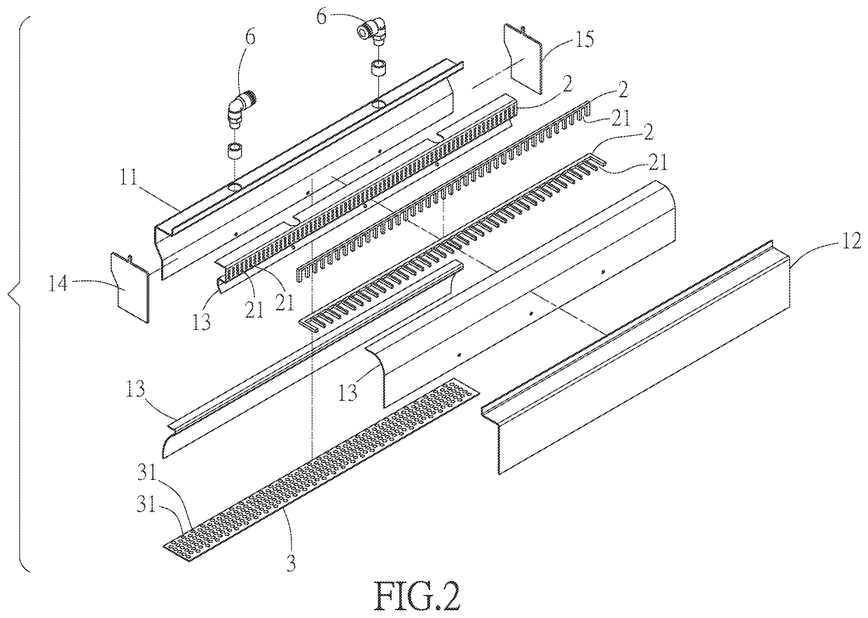

Referring to FIGS. 1 to 6, a gas curtain device for a front opening unified pod according to a first embodiment of the present invention comprises a casing 1, at least one first gas guide plate 2, and a second gas guide plate 3.

The casing 1 is composed of a left panel 11, a right panel 12 and a plurality of partitions 13 in cooperation with a front panel 14 and a rear panel 15. An interior space 16 is defined in the casing 1. The gas curtain device is disposed on the upper side of a door of a load port 7 of the front opening unified pod inside equipment front end module (EFEM).

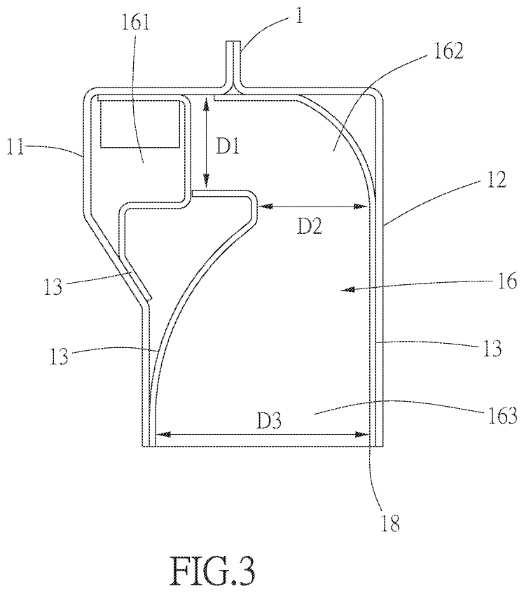

As shown in FIG. 3, the interior space 16 defines a transverse gas space 161, a curved gas space 162 communicating with the transverse gas space 161 and a vertical gas space 163 communicating with the curved gas space 162 according to the cross section of the casing 1. The area of the cross section at the distal end of the vertical gas space 163 is greater than the area of the cross section of the transverse gas space 161 and the area of the cross section of the curved gas space 162. In this embodiment, the dimension D2 of the cross section of the curved gas space 162 is greater than the dimension D1 of the cross section of the transverse gas space 161, and the dimension D3 of the cross section at the distal end of the vertical gas space 163 is greater than the dimension D2 of the cross section of the curved gas space 162. The top of the left plate 11 of the casing 1 has two gas inlets 17 communicating with the transverse gas space 161. The bottom end of the casing 1 has a gas outlet 18 communicating with the vertical gas space 163.

The first gas guide plate 2 is disposed in the transverse gas space 161 and/or the curved gas space 162. The first gas guide plate 2 has a plurality of first gas guide holes 21. In this embodiment, the at least one first gas guide plate 2 includes three first gas guide plates. One of the first gas guide plates 2 is disposed on one of the partitions 13 and is located in the transverse gas space 161. The other two first gas guide plates 2 are located in the curved gas space 162. The curved gas space 162 is a downward curved gas space. One of the other two first gas guide plates 2 is located at one end of the curved gas space 162 in the horizontal direction, and the other is located at another end of the curved gas space 162 in the vertical direction. In the first embodiment, the other two first gas guide plates 2 are replaceable structures.

The second gas guide plate 3 is disposed at one end of the vertical gas space 163 adjacent to the gas outlet 18. The second gas guide plate 3 has a plurality of second gas guide holes 31. The second gas guide holes 31 each have a circular shape. The second gas guide plate 3 is a replaceable structure.

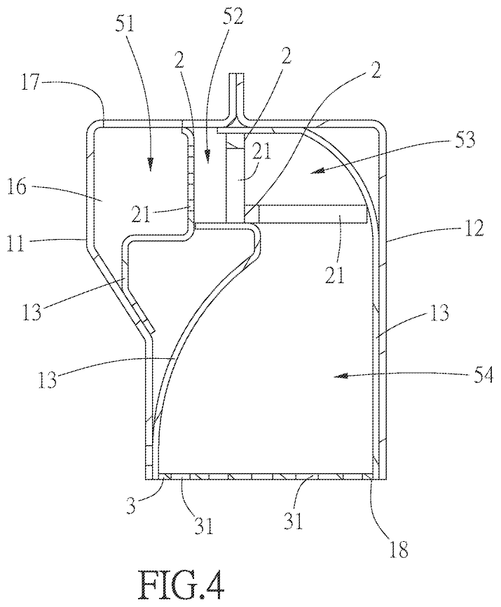

Further, as shown in FIG. 4, the number of the first gas guide plates 2 is three to partition the interior space 16 into at least one first gas space 51, a second gas space 52, a third gas space 53 and a fourth gas space 54. The first gas space 51 communicates with the gas inlet 17. The fourth gas space 54 communicates with the gas outlet 18. Based on the respective shapes of the partitions 13, the first gas space 51, the second gas space 52 and the third gas space 53 are located at the same height and adjacent to each other horizontally, and the fourth gas space 54 is below the third gas space 53.

Further, two of the first gas guide plates 2 are arranged opposite to each other. The first gas space 51 and the second gas space 52 communicates with each other in the horizontal direction via the first gas guide holes 21 passing through the two first gas guide plates 2 in the horizontal direction. Similarly, the second gas space 52 and the third gas space 53 communicates with each other in the horizontal direction. The other first gas guide plate 2 is arranged opposite to the second gas guide plate 3. Based on the shape of the curved gas space 162, the third gas space 53 is also a downward curved gas space. The third gas space 53 and the fourth gas space 54 communicates with each other in the vertical direction via the first gas guide holes 21 vertically passing through the other first gas guide plate 2.

In this embodiment, the first gas guide holes 21 of the first gas guide plate 2 partitioning the first gas space 51 and the second gas space 52 are in the shape of circular holes. The first gas guide holes 21 of the other first gas guide plates 2 are in the shape of a grating. The gas guide holes in the shape of a grating refer to that the gas guide holes are arranged at intervals, and the gas guide holes are elongate holes extending vertically. Accordingly, when the gas flow passes through the first gas guide holes 21 in the shape of a grating, the gas flow is regulated to flow with straight flow lines. The first gas guide holes 21 of the three gas guide plates 2 may be in the shape of circular holes or a grating, but not limited thereto.

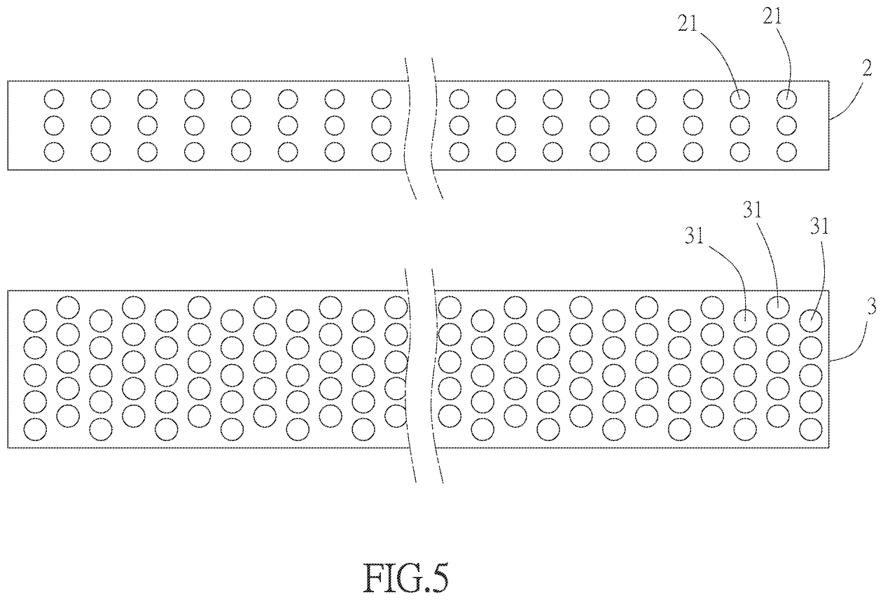

In addition, as shown in FIG. 5, the number of the second gas guide holes 31 provided by the present invention is greater than the number of the first gas guide holes 21, and the total area of the second gas guide holes 31 of the second gas guide plate 3 is greater than the total area of the first gas guide holes 21 of the first gas guide plate 2. A single first gas guide plate 2 is compared with the second gas guide plate 3 to obtain the number and the total area of the first gas guide holes 21 and the number and total area of the second gas guide holes 31. The less the number of gas guide holes and the less the total area of gas guide holes distributed on the gas guide plate, the faster the velocity of the gas flow and the lower the uniformity. Conversely, the greater the number of gas guide holes and the greater the total area of gas guide holes distributed on the gas guide plate, the slower the velocity of the gas flow and the higher the uniformity. Therefore, the velocity of the gas flow passing through the first gas guide plate 2 is fast, and the uniformity of the gas flow passing through the second gas guide plate 3 is high. The first gas guide plate 2 and the second gas guide plate 3 are replaceable structures for changing the number and the total area of the first gas guide holes 21 as well as the second gas guide holes 31, thereby regulating the velocity and uniformity of the gas flow passing through the first gas guide plate 2 and the second gas guide plate 3.

Furthermore, the second gas guide holes 31 are evenly distributed on the second gas guide plate 3. The first gas guide holes 21 may be distributed evenly or unevenly on the first gas guide plate 2. Similarly, the first gas guide plate 2 is a replaceable structure for adjusting the first gas guide holes 21 to be evenly distributed on the first gas guide plate 2, or the first gas guide holes 21 are distributed unevenly and concentrated at certain positions of the first gas guide plate 2, so as to adjust the gas flow passing through the interior space 16.

In addition, gas pipes 6 are connected to the two gas inlets 17 of the casing 1. respectively. The upper end of the gas pipe 6 is opened for introducing a clean and dry gas, and the lower end of the gas pipe 6 has an outlet 61. The outlet 61 of the gas pipe 6 is inserted into the corresponding gas inlet 17, so that the outlet 61 communicates with the first gas space 51.

It should be noted that because the dimension D2 of the cross section of the curved gas space 162 is greater than the dimension D1 of the cross section of the transverse gas space 161 and the dimension D3 of the cross section at the distal end of the vertical gas space 163 is greater than the dimension D2 of the cross section of the curved gas space 162. the gas sequentially flows through the gas spaces with gradually increased areas of the cross sections, so that the velocity of the gas flow is reduced when the gas is transported to the interior space 16. The curved gas space 162 allows the gas flow to stay in the interior space 16 for a longer period of time compared to the straight gas space. Through the different areas of the cross sections in cooperation with the curved gas space 162, the gas flow can be regulated to have different velocities and uniformities when the gas flow passes through the first gas guide plates 2 and the second gas guide plate 3 in the interior space 16. For example, in the present embodiment, the velocity of the gas flow passing through the first gas guide holes 21 is fast. Even if the velocity of the gas flow is slowed down by the curved gas space 162, when the gas flow passes through the second gas guide holes 31, the gas flow can be guided out uniformly at a proper speed.

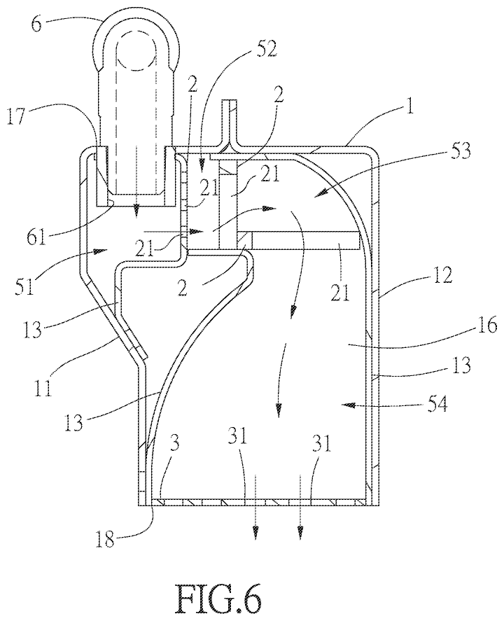

With the above structure of the present invention, when the gas is introduced into the casing 1 via the gas pipes 6, as shown in FIG. 6, the gas is first introduced into the first gas space 51 from each outlet 61 to form a gas flow. The gas flow in the first gas space 51 is guided into the second gas space 52 via the circular first gas guide holes 21. When the gas flow passes through the circular first gas guide holes 21, the velocity of the gas flow is accelerated because the number of the first gas guide holes 21 is less and the total area of the first gas guide holes 21 distributed on the first gas guide plate is less.

Then, the gas flow is guided into the third gas space 53 via the first gas guide holes 21 in the shape of a grating of another first gas guide plate 2. At this time, because the first gas guide holes 21 is in the shape of a grating, the gas flow is regulated to flow in the horizontal direction, and then flows downward along the shape of the third gas space 53. This allows the accelerated gas flow to be slowed down for a period of time to improve uniformity. Afterwards, the gas flow is guided into the fourth gas space 54 via the first gas guide holes 21 in the shape of a grating of the other first gas guide plate 2, so that the gas flow is regulated to flow downward with straight flow lines.

When the gas flow passes through the second gas guide holes 31 adjacent to the gas outlet 18, because the number and total area of the second gas guide holes 31 distributed on the second gas guide plate 3 are relatively large, when the gas flow passes through the second gas guide holes 31, the uniformity of the gas flow can be improved and the gas flow can be regulated to flow downward uniformly with straight flow lines, so as to ensure that the gas flow will flow uniformly with straight lines when it is blown out via the gas outlet 18. Finally, the uniform gas flow flowing with straight lines is discharged via the gas outlet 18.

The feature of the present invention is that through the design of the flow channel structure, the gas flow passes through the four gas guide plates to create a regulation effect. Besides, through the different areas of the cross sections in cooperation with the curved gas space 162, the gas flow can be regulated to have different velocities and uniformities when the gas flow passes through the first gas guide plates 2 and the second gas guide plate 3 in the interior space 16. Finally, when the gas flow passes through the second gas guide holes 31, the uniformity of the gas flow can be improved, and the gas flow can be regulated to flow uniformly with straight flow lines. Thus, it is ensured that the gas flow is discharged from the gas outlet 18 at a proper speed, is distributed uniformly and flows with straight flow lines. The present invention can reliably block moisture and fine particles and prevent moisture and fine particles from entering the front opening unified pod.

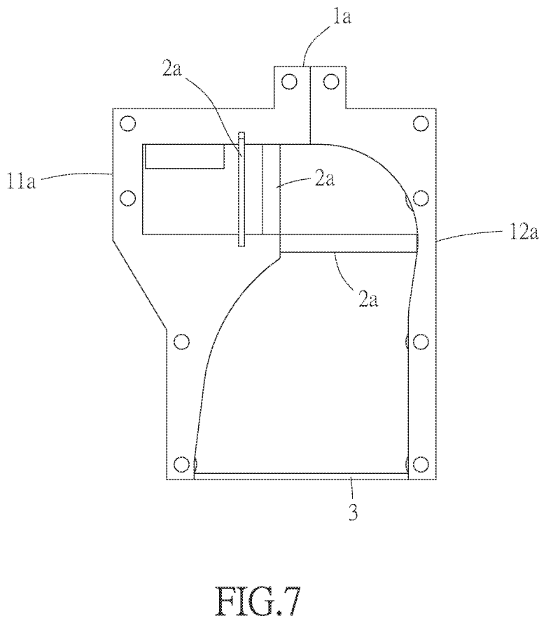

FIG. 7 illustrates a second embodiment of the gas curtain device for the front opening unified pod provided by the present invention. The second embodiment is substantially similar to the first embodiment with the exceptions described hereinafter. In the second embodiment, the casing la includes a left casing 11a and a right casing 12a joined to the left casing 11a. The three first gas guide plates 2a and the second gas guide plate 3 are all replaceable structures for changing the velocity and uniformity of the gas flow. The gas flow passes through the four gas guide plates to create a regulation effect. Similarly, the uniformity of the gas flow can be improved, and the gas flow can be regulated to flow uniformly with straight lines. It also plays the function of blocking fine particles and moisture. Thus, it is ensured that the gas flow is discharged from the gas outlet 18 at a proper speed, is distributed uniformly and flows with straight lines. The present invention can reliably block moisture and fine particles and prevent moisture and fine particles from entering the front opening unified pod.

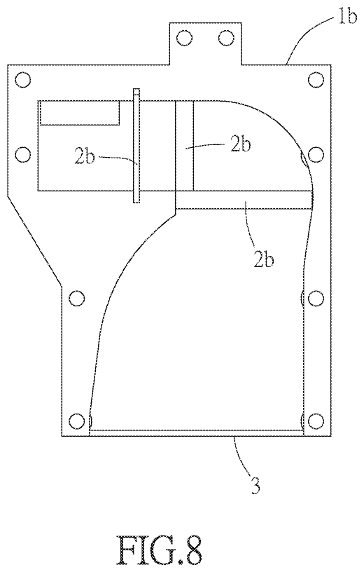

FIG. 8 illustrates a third embodiment of the gas curtain device for the front opening unified pod provided by the present invention. The third embodiment is substantially similar to the first embodiment with the exceptions described hereinafter. In the third embodiment, the casing 1b is integrally formed. The three first gas guide plates 2b and the second gas guide plate 3 are all replaceable structures for changing the velocity and uniformity of the gas flow. Similarly, the gas flow passes through the four gas guide plates to create a regulation effect, having the same function as in the first embodiment. The present invention can reliably block moisture and fine particles and prevent moisture and fine particles from entering the front opening unified pod.

What is claimed is:

1. A gas curtain device for a front opening unified pod, comprising:
a casing, having an interior space, the interior space defining a transverse gas space, a curved gas space communicating with the transverse gas space, and a vertical gas space communicating with the curved gas space according to a cross section of the casing, the casing having at least one gas inlet communicating with the transverse gas space and a gas outlet communicating with the vertical gas space;
at least one first gas guide plate, disposed in the transverse gas space and/or the curved gas space, the first gas guide plate having a plurality of first gas guide holes;
a second gas guide plate, disposed at one end of the vertical gas space adjacent to the gas outlet, the second gas guide plate having a plurality of second gas guide holes;
wherein the number of the second gas guide holes is greater than the number of the first gas guide holes, and a total area of the second gas guide holes of the second gas guide plate is greater than a total area of the first gas guide holes of the first gas guide plate.

2. The gas curtain device as claimed in claim 1, wherein an area of a cross section at a distal end of the vertical gas space is greater than an area of a cross section of the transverse gas space and an area of a cross section of the curved gas space.

3. The gas curtain device as claimed in claim 2, wherein the area of the cross section of the curved gas space is greater than the area of the cross section of the transverse gas space, and the area of the cross section at the distal end of the vertical gas space is greater than the area of the cross section of the curved gas space.

4. The gas curtain device as claimed in claim 1, wherein the at least one first gas guide plate includes three first gas guide plates, one of the first gas guide plates is disposed in the transverse gas space, and the other two first gas guide plates are disposed in the curved gas space.

5. The gas curtain device as claimed in claim 4, wherein the curved gas space is a downward curved gas space, one of the other two first gas guide plates is disposed at one end of the curved gas space in a horizontal direction, and the other is disposed at another end of the curved gas space in a vertical direction.

6. The gas curtain device as claimed in claim 4, wherein the first gas guide plates and the second gas guide plate are replaceable structures for changing the number and the total area of the first gas guide holes and the second gas guide holes, thereby regulating a velocity and a uniformity of a gas flow passing through the first gas guide plates and the second gas guide plate.

7. The gas curtain device as claimed in claim 6, wherein the first gas guide holes are distributed evenly or unevenly on the first gas guide plate for regulating the gas flow.

8. The gas curtain device as claimed in claim 1, wherein the casing includes a left panel, a right panel, and a plurality of partitions.

9. The gas curtain device as claimed in claim 1, wherein the casing includes a left casing and a right casing joined to the left casing.

10. The gas curtain device as claimed in claim 1, wherein the casing is integrally formed.
